(19) United States
(12) Patent Application Publication
(10) Pub. No.: US 2009/0079450 A1
(43) Pub. Date: Mar. 26, 2009

(54) SEMICONDUCTOR TEST DEVICE

(75) Inventors: Udo Hartmann, Neuried (DE); Frank Pietzschmann, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/057,909

(22) Filed: Mar. 28, 2008

(30) Foreign Application Priority Data
Mar. 29, 2007 (DE) 10 2007 015 284.3

(51) Int. Cl. G01R 31/26

(52) U.S. Cl. 324/754

(57) ABSTRACT

A semiconductor test device. In one embodiment, the test device includes a drill bit. The test device is configured to rotate the drill bit, at least after contacting the semiconductor device, for penetrating into the semiconductor device.

### CROSS-REFERENCE TO RELATED APPLICATIONS

This Utility Patent Application claims priority to German Patent Application No. DE 10 2007 015 284.3 filed on Mar. 29, 2007, which is incorporated herein by reference.

### BACKGROUND

The invention relates to a test device for semiconductor devices and to a method for testing semiconductor devices.

Semiconductor devices, e.g., corresponding, integrated (e.g., analog or digital and/or mixed-signal) circuits, semiconductor memory devices such as, for instance, functional memory devices (PLAs, PALs, etc.) and table memory devices (e.g., ROMs or RAMs, in particular SRAMs and DRAMs), etc. are subject to comprehensive tests, e.g., in the semi-finished and/or finished state, at a plurality of test stations.

For testing the semiconductor devices, a corresponding semiconductor device test device may be provided at the respective test station which generates the test signals required for testing the semiconductor devices.

For instance, at a first test station, the signals required for testing the semiconductor devices that are still available on the wafer may, for instance, be generated by a test device that is connected with a corresponding semiconductor device test card (“probe card”), and may be input in the respective contact fields of the semiconductor devices by using corresponding needle-shaped connections (“contact needles”) provided at the test card.

The signals output by the semiconductor devices at corresponding contact fields in reaction to the input test signals are tapped by corresponding, needle-shaped connections (“contact needles” or “test needles”) of the probe card, and (e.g., via a corresponding signal line that connects the probe card with the test device) transmitted to the test device where an evaluation of the corresponding signals can take place.

After the sawing apart of the wafer, the devices, that are then available individually, can each be loaded individually in carriers (i.e. a corresponding package) and be transported further to a further test station.

At the further test station, the carriers are inserted in corresponding adapters or sockets, that are connected with a (further) test device —, and then the device that is available in the respective carrier is subject to corresponding (further) test methods.

For testing the semiconductor devices available in the carriers, the corresponding test signals output by the test device are transmitted to the corresponding contact fields of the respective semiconductor device via the adapter and the carrier (or corresponding connections of the carrier, respectively).

The signals output by the semiconductor devices at corresponding contact fields in reaction to the input test signals are tapped by corresponding carrier connections and transmitted, via the adapter (and a corresponding signal line connecting the adapter with the test device), to the test device where an evaluation of the corresponding signals can take place.

In a correspondingly similar manner, the semiconductor devices may, for instance, also be tested after their final incorporation in corresponding device packages (e.g., corresponding plug or surface-mountable packages), and/or after the incorporation of the packages, provided with corresponding semiconductor devices, in corresponding electronic modules, etc.

Conventional test bodies, e.g., a contact needle, perform a linear scratching movement on the contact field and thus scratch themselves into the contact field material so as to ensure a good contact. It is a disadvantage that the following effects may occur in so doing:

a) The contact resistance depends i.a. on the depth of penetration, the scratching length, a contamination of the needle (and partially of the contact field), and the contact pressure. In a typical test process, the needle field and the contact field are driven over each other (e.g., in that a chuck drives a wafer fastened thereon on the contact field) and are, after the contacting of the needles on the contact field, continued to be approached, frequently approx. 20 μm to 100 μm), so that the needle can dig into the contact field (“overdrive”). A good, since low, contact resistance can then be put into practice only at high contact pressure, long scratching length, and high depth of penetration with a clean needle.

b) The scratching length depends on the contact pressure and the needle cinematic during the overdrive.

c) Due to a non-ideal planarity of the needle field, some needles contact the contact field earlier than other ones and thus produce a longer scratch since they experience more overdrive.

d) By the scratching process, the needles take up contact field material that collects at the needle tip and ‘adheres’ to it. This may result in a self-reinforcement: the contamination causes a higher transition resistance which in turn effects a higher voltage drop at the needle, which causes more heat, so that even more contact field material ‘combusts’ or ‘adheres’, which causes an even higher transition resistance, etc.

e) The contact pressure is a function of the overdrive. With most probe cards, this relation is linear: much overdrive generates a high contact pressure.

By these effects, the contact becomes less defined and may thus falsify the test result.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate similar parts.

FIG. 1 illustrates a schematic representation of the basic structure of a semiconductor device test system with a test card and a test device connected thereto, as used for testing semiconductor devices arranged on a wafer.

FIG. 2 illustrates a further schematic representation of a conventional test system.

FIG. 3 illustrates a schematic force path diagram of the conventional arrangement of FIG. 2.

FIG. 4 illustrates an inclined view of a scratch trace in a contact field which was applied by using an arrangement according to FIG. 2.

FIG. 5 illustrates a side view of a test body tip according to one embodiment.

FIG. 6 illustrates a view of the test body tip according to FIG. 5.

FIG. 7 illustrates a side view of a test body tip according to one embodiment, and a view of the test body tip.

FIG. 8 illustrates a side view of a test body tip according to one embodiment, and a view of the test body tip.

FIG. 9 illustrates a side view of a spring element of a test body according to one embodiment in a first position.

FIG. 10 illustrates a side view of the spring element of FIG. 9 in a second position.

FIG. 11 illustrates a side view of a spring element of a test body according to one embodiment in a first position.

FIG. 12 illustrates a side view of the spring element of FIG. 11 in a second position.

FIG. 13 illustrates a side view of a test body with a spring element according to one embodiment.

FIG. 14 illustrates a schematic force path diagram graph of the spring element according to one embodiment.

FIG. 15 illustrates a sketchy side view of a test body.

FIG. 16 illustrates a side view of a further test body in a guide.

FIG. 17 illustrates a view of a circumference of the test body of FIG. 16 in an unrolled form.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One or more embodiments provide a possibility of ensuring a defined contact between a test body and a contact field during a semiconductor test, in one embodiment with the edge conditions: low contact resistance, small impression, low depth of penetration, self purification of the test body, and/or overdrive independence of the contact pressure.

In one embodiment, there is used a test device for semiconductor devices, in one embodiment a probe card, including at least one contact test body for contacting a semiconductor device (e.g., a wafer or an individualized device). The contact test body includes a drill bit, and the test device is adapted to rotate the drill bit, at least after getting into contact with the semiconductor device, for penetrating into the semiconductor device.

In one embodiment, the drill bit is provided with at least one cutting edge.

In one embodiment, the drill bit is connected with at least one torsion spring that generates a rotation about the shift direction on expansion in a shift direction (e.g., z-direction) of the contact test body.

In one embodiment, the torsion spring includes two carrier elements that are connected by two helically arranged struts.

In one embodiment, the drill bit is connected with at least one spring with a non-proportional spring characteristic such that its spring constant, after attaining a predetermined shift path of the contact test body, decreases significantly for a further shift path.

In one embodiment, the spring constant of the spring with a non-proportional spring characteristic drops substantially to Zero after attaining the predetermined shift path.

In one embodiment, the contact test body is a plug gauge which is mounted in a guide of the test device for linear shifting and which is designed such that, on shifting in the guide, the plug gauge is, at least over a predetermined shift path in longitudinal direction, forced to make a rotation about its longitudinal axis. In one embodiment, this plug gauge has a longitudinal groove in its circumference which has a helical design at least partially about the longitudinal direction, and which is mounted in the guide by balls running in the longitudinal groove.

In one embodiment, there is used a method for testing semiconductor devices by using at least one contact test body of a test device for contacting a contact field of a semiconductor device with increasing contact pressure, wherein the method includes at least the following step: rotating the contact test body on the contact field, wherein the contact test body includes a drill bit.

In one embodiment, the drill bit is equipped with at least one cutting edge.

In one embodiment, the rotating of the contact test body is caused by a torsion spring which is compressed by a contact pressure of the contact test body, and which converts the compression at least partially in a rotation. In one embodiment, the torsion spring includes two carrier elements that are connected by helically arranged struts.

In one embodiment, the drill bit is connected with at least one spring with non-proportional spring characteristic, wherein the spring is switched to a lower spring constant after achieving a predetermined contact pressure. In one embodiment, after the switching of the spring with non-proportional spring characteristic to a lower spring constant, a further shifting of the contact test body is performed with a substantially constant force.

In one embodiment, the contact test body is a plug gauge that is mounted in a guide of the test device for linear shifting, wherein, with a shifting in the guide, the plug gauge is, at least over a predetermined shift path in longitudinal direction, forced to rotate about its longitudinal axis. In one embodiment, the plug gauge includes a longitudinal groove in its circumference which has a helical design at least partially about the longitudinal direction, and which is mounted in the guide by balls running the longitudinal groove.

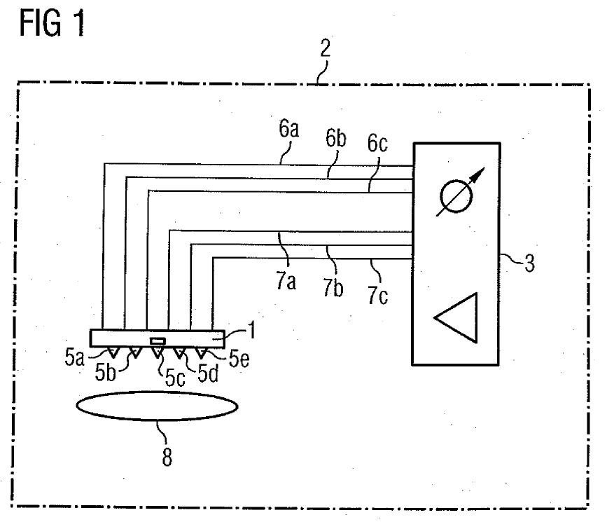

FIG. 1 illustrates a schematic representation of a basic structure of a test station 2 for testing semiconductor devices arranged or manufactured on a wafer 8.

The semiconductor devices to be tested which are still available on the wafer 8 (e.g., of silicon or another suitable semiconductor material such as GaAs) may, for instance, be integrated (analog, digital, and/or mixed-signal) circuits or single semiconductors, and/or semiconductor memory devices such as, for instance, functional memory devices (PLAs, PALs, etc.), or table memory devices (e.g., ROMs or RAMS), in one embodiment SRAMs or DRAMs, e.g., semiconductor devices using a clock frequency higher than 500 MHz, in one embodiment higher than 1 GHz (here e.g., DRAMs (Dynamic Random Access Memories or dynamic read-write memories) with double data rate (DDR-DRAMs=Double Data Rate-DRAMs)). The invention is, however, not restricted to a particular kind of semiconductors.

The test signals required for testing the semiconductor devices that are still available on the wafer 8 are transmitted by a test device 3 (here: a digital ATE test device) via one or a plurality of signal lines (“driver channels” 6a, 6b, 6c) to a semiconductor device test card or probe card 1 and, via contact needles 5a, 5b, 5c, 5d, 5e provided at the probe card, to contact fields (“pads”) provided on the semiconductor devices.

As results from FIG. 1, the contact needles 5a, 5b, 5c, 5d, 5e extend from the bottom of the probe card 1 downward in the direction of the wafer 8.

The signals output in reaction to the input test signals at semiconductor device connections or contact fields are, ly inversely as described above, tapped by contact needles 5a, 5b, 5c, 5d, 5e of the probe card 1 and supplied, via one or a plurality of signal lines (“comparator channels” 7a, 7b, 7c) to the test device 3 where an evaluation of the signals can then take place. The driver channels and comparator channels may also be comprehended in joint input/output channels.

As results from FIG. 1, the above-mentioned probe card 1, the semiconductor devices to be tested (or the wafer 8 or on the wafer 8, respectively), and possibly also the above-mentioned test device 3 are arranged at the test station 2 in a subsystem secluded from the environment (e.g., a micro one-space system).

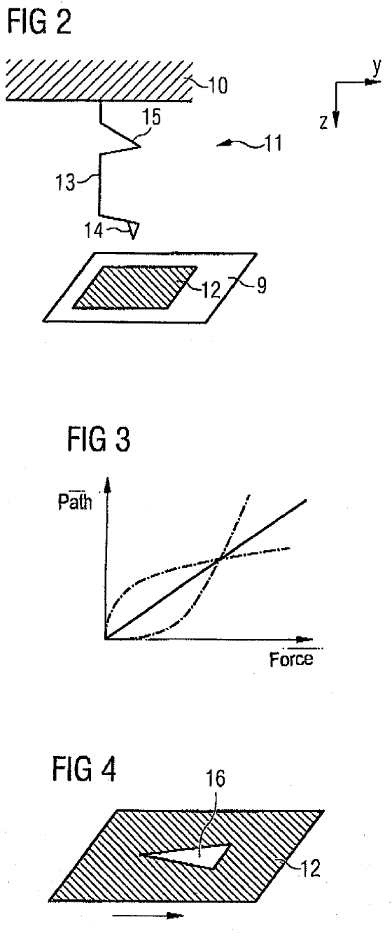

FIG. 2 illustrates a known probe card 10 with an example test body 11 fixed to the bottom thereof for contacting a contact field 12 of a semiconductor device 9. The test body 11 is here designed as a test needle 13 that includes a test body tip or test needle tip 14 for contacting the contact field (“pad”) 12. The test needle 13 is suspended on a spring element 15.

For the testing of the device, the semiconductor device or the wafer is approached such to the probe card 10 with the test needle 13 in z-direction, e.g., by using moving the chuck holding the wafer, that the test needle tip 14 contacts the contact field 12. Even after the contacting, the approaching of the test card 10 and the contact field 12 or semiconductor device, respectively, is continued (“overdrive”). In so doing, the test body 11 is shifted relatively against the remaining test card 12 in z-direction, so that the spring element 15 is compressed, which thus generates a contact pressure between the test body 11 or the test needle 13, respectively, and the contact field 12. As the approaching is continued, the contact pressure will continue to increase. At the same time, the probe card 10 and the semiconductor device and thus the contact field 12 are shifted laterally relatively to each other along the y-direction. Thus, the test needle tip 14 generates a typical scratch trace on the contact field 12 with increasing contact pressure across the shift path y.

FIG. 3 illustrates a schematic force path diagram of the arrangement of FIG. 2. Ideally, a linear relation between force and shift or path (in z-direction) would also be given in the scratching process, as is illustrated by the straight line drawn through. In reality, however, due to variable friction forces, forming of bulges, contamination, lacking planarity of the contact field, non-linearity of the spring, etc., the force path curves may deviate considerably from the ideal line, as is indicated by the dashed lines.

FIG. 4 illustrates an inclined view of a scratch trace 16 in a contact field 12 in which the test needle tip 14 was, with increasing contact pressure or continued approaching, respectively, drawn from the left to the right, as is indicated by the arrow. The scratch trace 16 broadens and deepens as the scratch length increases.

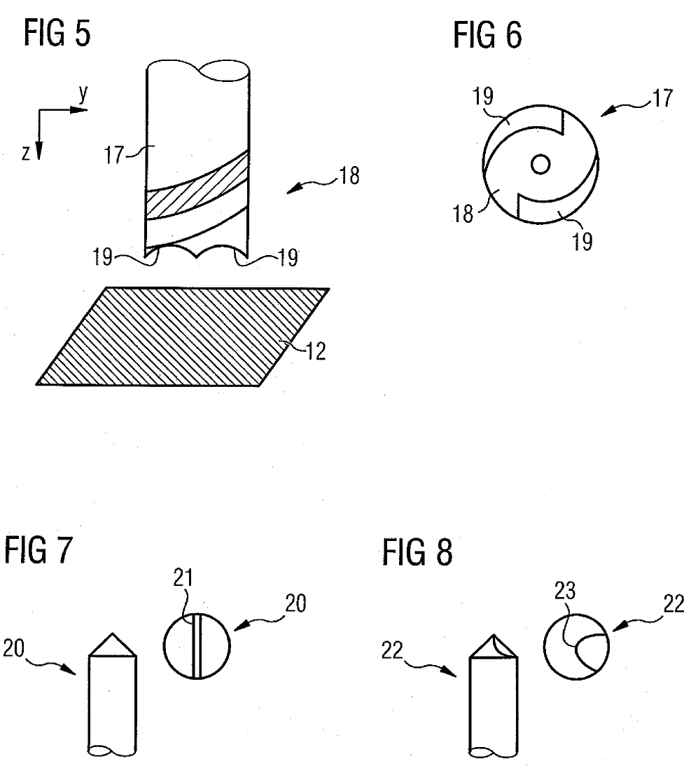

FIG. 5 illustrates a side view of a test body 17 according to a first embodiment. The test body 17 is designed as a drill in the region of the test body tip 18. In other words, the test body 17 has a drill bit 18 as test body tip. In the embodiment illustrated, the pertaining front face is equipped with cutting edges 19 so as to enable or facilitate a penetration of the test body 17 in the contact field 12. By the rotating/drilling movement, a lower contact resistance is achieved by a good contact of the test body tip 18 with the material of the contact field 12. There is no “slipping” on the pollution of the contact field 12 nor any contamination of the test body tip 18.

FIG. 6 illustrates a view from the bottom on the front face of the test body tip 18 of the test body 17 of FIG. 5 in which the position of the cutting edges 19 is further illustrated.

FIG. 7 illustrates a side view of a test body tip 20 according to one embodiment (left chart), and a view from the bottom on the front face of the test body tip 20 (right chart). The only cutting edge 21 is positioned linearly and centrally across the breadth of the front face.

FIG. 8 illustrates a side view of a test body tip 22 according to one embodiment (left chart), and a view from the bottom of the front face of the test body tip 22 (right chart). The only cutting edge 23 is positioned in an arcuate manner at the front face.

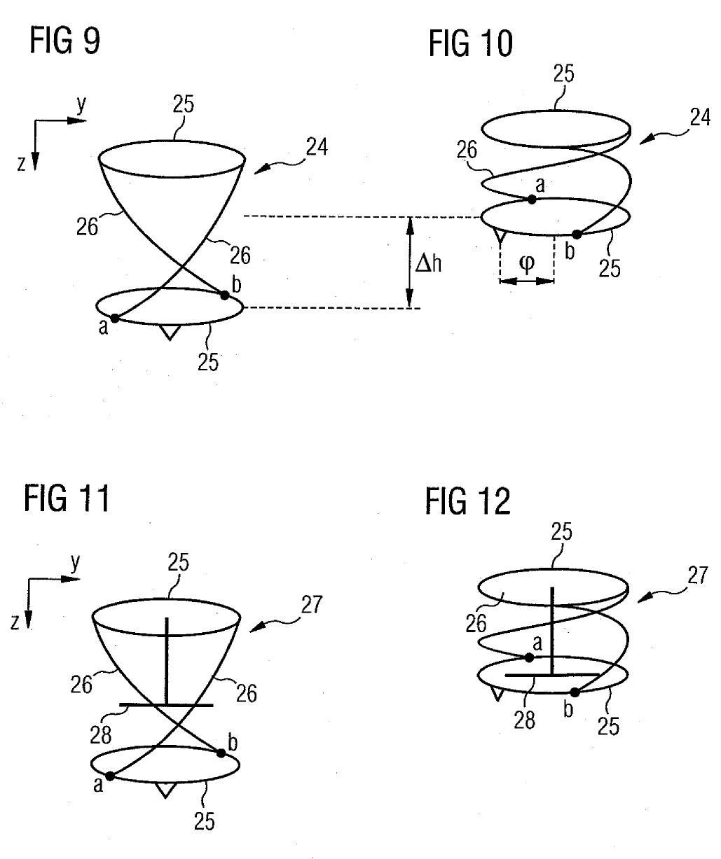

FIG. 9 illustrates a side view of a spring element 24 of a test body for suspending a test body tip according to one embodiment in a first position. The spring element 24 includes relatively rigid carrier elements 25 that are staggered in z-direction to the top and to the bottom, and that are connected by bent elastic struts 26. The contact points of the struts 26 with the bottom carrier element 25 are marked by a and b. The bottom carrier element 25 (in z-direction) is followed by the test body tip. The struts 26 are, in addition, rotated about the z-axis, so that, when the spring element is compressed in z-direction, the force applied in z-direction is at least partially deflected in a force perpendicular thereto. Thus, the two carrier elements 25 are twisted against each other about the z-axis. In the released state illustrated in FIG. 9, the torsion spring element 24 is substantially positioned on an outer contour of a cylinder.

FIG. 10 illustrates the torsion spring element 24 of FIG. 9 in a second position that is compressed by Δh in z-direction, with a retained upper carrier face 25. The contraction by Δh produces, by a bending of the struts 26, a rotation φ about the z-axis by the spring element 24, as is indicated by the arrow (see also the position of the contact points a, b in comparison to FIG. 9).

FIGS. 11 and 12 illustrate a representation of a torsion spring element 27 which is analog to that of FIGS. 9 and 10. Compared with the spring element 24 of FIGS. 9 and 10, the torsion spring element 27 additionally fastens a restricting element in the form of a stopper 28 that is formed in the spring element 27 in the form of a downward “T”, e.g., securely on the upper carrier element 25. On compression of the spring element 27, with a particular contraction path Δh, a pertinent rotation φ is achieved in which the struts 26 abut the stopper 28, so that a further twisting is prevented. Without a twisting, a further penetration of the test body is substantially also prevented. By this restriction, it is possible to achieve a defined, constant impression of the test body or of the test body tip, respectively, which remains always in the region of the test body tip. By the restriction of the rotating/drilling movement it may also be achieved that it ranges distinctly below the chip length of the contact field material.

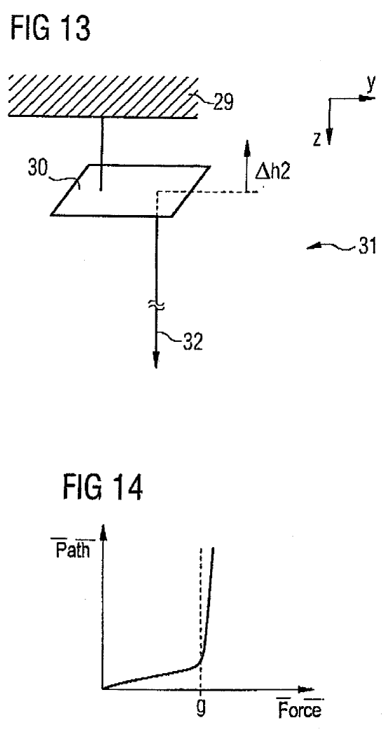

FIG. 13 illustrates a side view of a test body 31 with a pertinent test body tip 32 which is fastened to a probe card 29 via a spring element 30, according to a third embodiment. The spring element 30 has a non-proportional spring characteristic as is, for instance, illustrated by using the force path diagram illustrated in FIG. 14. On shifting of the non-proportional spring element 30 in z-direction, such as, for instance, on impressing the test body 31 in the contact field, the force required is substantially linear to the shift path Δh2 until a switching value g of the force (or a switching point, respectively) of the (shift) path since the contacting is attained. On or after attaining the switching value g, the spring element substantially resigns for further force increments. In other words, hardly any further force has to be spent for a further shifting in z-direction after the switching value has been attained. By this embodiment, it is possible to restrict a force or load on the test body tip or on the contact face of test body tip and contact field, and thus effectively the depth of penetration in a defined manner, which further reduces the danger of damage to the contact field.

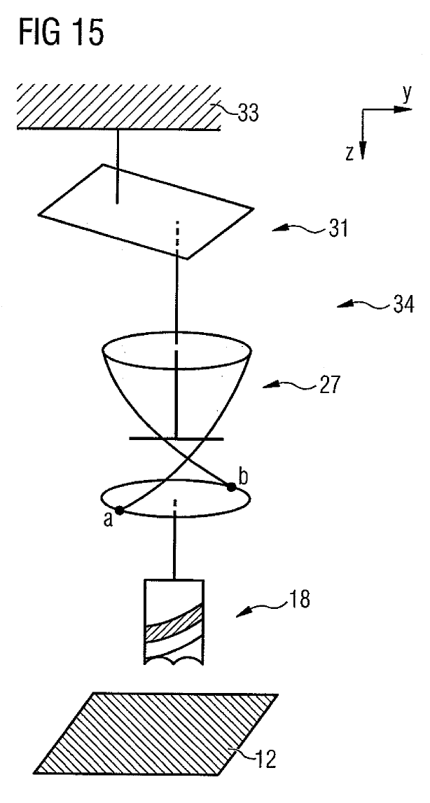

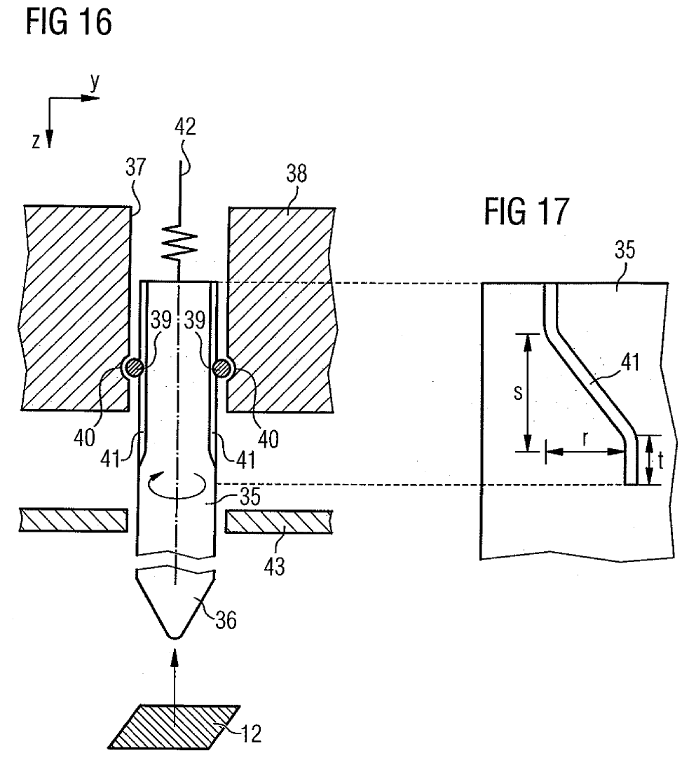

FIG. 15 illustrates a sketchy side view of a test body 34 that is positioned at a probe card 33. The test body 34 is constructed such that it includes a drill bit 18 according to FIGS. 5 and 6 at its tip, thereabove, in the direction of the suspension, a torsion spring element 27 according to FIGS. 11 and 12, and again thereabove a non-proportional spring element (“clicker spring”) 31 according to FIGS. 13 and 14. The suspension of the drill bit 18 at the torsion spring 27 is designed to be sufficiently rigid to transfer the twisting of the torsion spring 27 to the drill bit 18. The spring constant in z-direction of the torsion spring 27 is smaller than the spring constant of the clicker spring 31. The load path of the probe card 33 thus extends through these individual components that are connected in series. Since these individual components have already been described above, their respective functioning as such will not be dealt with here.

After contacting the contact field 12, the test body 34 is first of all continuously pressed on the contact field 12 with increasing contact pressure (“overdrive”). Thus, the torsion spring element 27 is first of all compressed and thus applies a rotation to the drill bit 18 that consequently drills into the contact field 12. After reaching the stopper of the torsion spring element 27, the rotating movement of the drill bit 18 is stopped. Furthermore, the torsion spring 27 behaves in z-direction like a substantially rigid element; the contact pressure is thus determined substantially by the clicker spring 31. On further shifting or further increased contact pressure, respectively, the switching value of the clicker spring 31 is attained, so that no more substantial additional load is transmitted to the drill bit 18 from then on. Thus, it is possible to adjust a maximum contact pressure so as to reproducibly adjust, for instance, the impression of the drill bit 18 in the contact field 12. The switching value (“click point”) of the clicker spring 31 may also be adjusted such that it releases prior to the abutment of the torsion spring. The test body 34 is thus capable of contacting the contact field 12 in a defined manner and reliably by largely avoiding damages.

FIG. 16 illustrates a side view of a further test body in the form of a plug gauge 35 with a substantially cylindrical body and a test body tip 36 tapering downward in contact direction to the contact field 12. The plug gauge 35 runs in a guide 37 in the form of a long hole or thread channel in the test card 38. The plug gauge 35 is mounted in the guide 37 by using balls 39 which are, on the one hand, held to be rotated, but not substantially shifted, in a depression 40 in the guide 37. On the other hand, the balls 39 run in a longitudinal groove 41 that is applied in the circumference of the plug gauge 35. The longitudinal groove 41 is shaped as illustrated in FIG. 17 that illustrates the unrolled circumference of the plug gauge 35 in part. The plug gauge 35 is held by a retention spring 42 and guided through an interrupted screen 43, and possibly protected.

FIG. 17 illustrates that the groove 41 extends helically in z-direction over a height s, wherein the height s and the circumferential length r define the relation of inclination. The helical section of the groove 41 is followed at the bottom by a straight section of the height t as a rotating and shifting stopper, as will be explained in more detail further below. By the relation of inclination r/s or s/r, a defined forced rotation of the plug gauge 35 about its longitudinal axis (that is oriented in z-direction) is generated as a function of its relative shifting in z-direction in the guide 37. If this relative shifting is performed by the starting of driving of the test card 38 after contacting the contact field 12 by the test tip 36 (“overdrive”), it is possible for the test tip 36 to drill into the contact field. To this end, the test tip 36 may, for instance, be designed as illustrated in FIGS. 5 to 8. After achieving the straight section t of the longitudinal groove 41 in z-direction by the balls 39, a further rotation is prevented. After a further shifting of the test body 35 in z-direction by the amount t, the balls 39 reach their stopper, and the plug gauge 35 does not move further relative to the guide 37, i.e. neither linearly nor rotationally.

The restriction of the rotating/drilling movement enables it to be distinctly below the chip length of the contact field material. Moreover, contamination or chips adhering to the plug gauge 35 may be stripped off in the guide. By turning back during the contacting, a further ‘stripping off’ of the contact field material is provided for.

Of course, the invention is not restricted to the above embodiments, but may, for instance, include different modifications and combinations.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor test device for semiconductor devices, comprising:
at least one contact test body for contacting a semiconductor device,
wherein the contact test body comprises a drill bit; and
wherein the test device is configured to rotate the drill bit, at least after contacting the semiconductor device, for penetrating into the semiconductor device.

2. The test device of claim 1, comprising wherein the drill bit is equipped with at least one cutting edge.

3. The test device claim 1, comprising wherein the drill bit is connected with at least one torsion spring that causes a rotation about the shifting direction on expansion in a shifting direction of the contact test body.

4. The test device of claim 3, wherein the torsion spring comprises two carrier elements that are connected by using helically arranged struts.

5. The test device of claim 1, comprising wherein the drill bit is connected with at least one spring with non-proportional spring wherein its spring constant decreases significantly for the further shift path after achieving a predetermined shift path of the contact test body.

6. The test device of claim 5, comprising wherein the spring constant of the spring with non-proportional spring substantially drops to Zero after achieving the predetermined shift path.

7. The test device of claim 1, comprising wherein the contact test body is a plug gauge which is mounted in a guide of the test device for linear shifting, and which is equipped such that, when shifted in the guide, the plug gauge is forced to rotate about its longitudinal axis at least over a predetermined shift path in longitudinal direction.

8. The test device of claim 7, comprising wherein the plug gauge comprises a longitudinal groove in its circumference which has a helical design at least partially about the longitudinal direction, and is mounted in the guide by balls running in the longitudinal groove.

9. A method for testing semiconductor devices comprising:
using at least one contact test body of a test device for contacting a contact field of a semiconductor device with increasing contact pressure;
rotating the contact test body on the contact field, and
wherein the contact test body comprises a drill bit.

10. The method of claim 9, comprising equipping the drill bit with at least one cutting edge.

11. The method of claim 9, comprising generating the rotating of the contact test body by a torsion spring compressed by a contact pressure of the contact test body and converting the compression at least partially in a rotation.

12. The method of claim 11, wherein the torsion spring comprises two carrier elements that are connected by helically arranged struts.

13. The method of claim 9, comprising connecting the drill bit with at least one spring with non-proportional spring characteristic, wherein the spring is switched to a lower spring constant after achieving a predetermined contact pressure.

14. The method of claim 13, comprising performing, after the switching of the spring with non-proportional spring characteristic to a lower spring constant, a further shifting of the contact test body with a substantially constant force.

15. The method of claim 9, comprising wherein the contact test body is a plug gauge mounted in a guide of the test device for linear shifting, wherein, with a shifting in the guide, the plug gauge is forced to rotate about its longitudinal axis at least over a predetermined shift path in longitudinal direction.

16. The test device of claim 15, wherein the plug gauge comprises a longitudinal groove in its circumference which has a helical design at least partially about the longitudinal direction, and which is mounted in the guide by balls running in the longitudinal groove.

17. A semiconductor test device comprising:
a mount configured to hold a semiconductor device including a probe card;
at least one contact test body for contacting a semiconductor device,
wherein the contact test body comprises a drill bit; and
wherein the test device is configured to rotate the drill bit, at least after contacting the semiconductor device, for penetrating into the semiconductor device.

18. The test device of claim 17, comprising wherein the drill bit is equipped with at least one cutting edge.

19. The test device claim 17, comprising wherein the drill bit is connected with at least one torsion spring that causes a rotation about the shifting direction on expansion in a shifting direction of the contact test body.

20. The test device of claim 19, wherein the torsion spring comprises two carrier elements that are connected by using helically arranged struts.

21. The test device of claim 17, comprising wherein the drill bit is connected with at least one spring with non-proportional spring wherein its spring constant decreases significantly for the further shift path after achieving a predetermined shift path of the contact test body.

22. The test device of claim 21, comprising wherein the spring constant of the spring with non-proportional spring substantially drops to Zero after achieving the predetermined shift path.

23. The test device of claim 17, comprising wherein the contact test body is a plug gauge which is mounted in a guide of the test device for linear shifting, and which is equipped such that, when shifted in the guide, the plug gauge is forced to rotate about its longitudinal axis at least over a predetermined shift path in longitudinal direction.

24. The test device of claim 23, comprising wherein the plug gauge comprises a longitudinal groove in its circumference which has a helical design at least partially about the longitudinal direction, and is mounted in the guide by balls running in the longitudinal groove.

25. A method for testing semiconductor devices comprising:
holding a semiconductor device;
using at least one contact test body of a test device for contacting a contact field of a semiconductor device with increasing contact pressure;
rotating the contact test body on the contact field, and
wherein the contact test body comprises a drill bit.
